(19) United States
(12) Patent Application Publication
(10) Pub. No.: US 2013/0047859 A1
(43) Pub. Date: Feb. 28, 2013

(54) ELECTROSTATIC PRECIPITATOR CELL WITH REMOVABLE CORONA UNIT

(71) Applicant: John R. Bohlen, Rickman, TN (US)

(72) Inventor: John R. Bohlen, Rickman, TN (US)

(21) Appl. No.: 13/222,637

(22) Filed: Aug. 31, 2011

(51) Int. Cl. B03C 3/47; H05F 3/02; H05K 13/00

(52) U.S. Cl. 96/80; 96/87; 29/592.1; 361/220

(57) ABSTRACT

A corona wire assembly including a first supporting member including a retaining device; a second supporting member including a retaining device; a corona wire capable of carrying a high voltage disposed between the first supporting member and the second supporting member; a ground discharge electrode disposed between the first supporting member and the second supporting member; wherein the corona assembly is separately installed and removed from an electrostatic precipitator is described. Current to the corona wire assembly can be tied to a fan assembly speed.

### CROSS-REFERENCE

U.S. Patent Application Publication No. 2011/0033346 A1 (U.S. patent application Ser. No. 12/535,520), filed Aug. 4, 2009 is incorporated herein in its entirety by reference.

### TECHNICAL FIELD

The present teachings are directed toward the improved cleaning capabilities of air cleaners utilizing electrostatic precipitators. In particular, the disclosure relates to a removable corona wire assembly that allows fast, convenient replacement of an ionizer in electrostatic precipitators.

### BACKGROUND

Air purifiers are widely used for removing foreign substances from the air. The foreign substances can include dust, dander, pollen, pollutants, smoke, VOCs, ozone etc. In addition, an air cleaner can be used to circulate room air. Air cleaners can be used in many settings, including in homes and offices.

Air purifiers utilizing electrostatic precipitators function by creating an electrical field. Dirt and debris in the air become ionized when they are brought into the electrical field by an airflow through the air cleaner. Charged positive and negative electrodes in the electrostatic precipitator air cleaner, such as positive and negative plates or positive and grounded plates, create the electrical field and one of the electrode polarities attracts the ionized dirt and debris. Periodically, the electrostatic precipitator can be removed and cleaned. Air purifiers utilizing electrostatic precipitators have many advantages over standard air purifiers utilizing mesh or carbon filters. Electrostatic precipitators can filter air more efficiently and can filter out smaller particles than traditional air purifiers. Further, there is little, or no pressure change across an electrostatic precipitator.

A need has been recognized in the air purifier industry for air purifier units with increased longevity. Over time, some parts or accessories for an air cleaner need maintenance or replacement. For example, corona wire elements break or become inefficient at carrying an electrical current over time. These corona wires may be under constant tension, carry uneven current, are subjected to a variety of climate conditions in the room where the unit is utilized, which can vary in heat or humidity, or the amount of particulate in the air. Additionally, often times regular cleaning or maintenance of electrostatic precipitator collection plates results in accidental damage to corona wires in an electrostatic precipitator. Thus, the prior art air purifiers utilizing electrostatic precipitators require periodic replacement of corona wires. However, the replacement of prior art corona wires in electrostatic precipitators has many drawbacks. Often times a user only replaces a single, visibly broken corona wire at a time. However, the replacement of only the visibly broken wires does not improve the efficiency of corona wires that have not broken, but have become inefficient. As such, the air cleaner may not be performing at maximum capacity. Further, the replacement of corona wires may be tedious and cumbersome, requiring the handling of multiple small parts to corona wire retaining members and associated fasteners.

The prior art does not, however, exemplify air purifiers utilizing electrostatic precipitators with easy, convenient mechanisms which facilitate the operator's ability to replace all of the corona wires at the same time.

### SUMMARY

According to one embodiment, a corona wire assembly is described. In one embodiment, a corona wire assembly comprises a first supporting member including a retaining device; a second supporting member including a retaining device; a corona wire capable of carrying a high voltage disposed between the first supporting member and the second supporting member; and a ground discharge electrode disposed between the first supporting member and the second supporting member; wherein the corona assembly is separately installed and removed from an electrostatic precipitator.

In some embodiments, the corona wire assembly comprises a plurality of corona wires, and the ground discharge electrode comprises a plurality of ground discharge electrodes interspersed between the corona wires.

In some embodiments, the corona wire assembly further comprises an electrical contact for connecting to an off-assembly power supply disposed on an outer planar surface of the first supporting member.

In some embodiments, the retaining devices comprise projections, tabs, or planar surfaces, and are releasably retained in an electrostatic precipitator by a corresponding groove, slot, hole, or by friction fit.

In some embodiments, each of the first and second members comprises a retaining slot for retaining the corona wire.

According to various embodiments, an air cleaner comprising an air duct including an inlet and an outlet, an electrostatic precipitator cell comprising a corona wire assembly and a collection assembly positioned in the air duct is described. In some embodiments, the collection plate assembly is positioned downstream of the corona wire assembly. In some embodiments, the corona wire assembly is installed and removed from the electrostatic precipitator cell and comprises: a first supporting member including a retaining device, a second supporting member including a retaining device, a corona wire capable of carrying a high voltage disposed between the first supporting member and the second supporting member, and a ground discharge electrode disposed between the first supporting member and the second supporting member.

In some embodiments, the air cleaner further comprises a tab on an outer surface of the corona wire assembly; and a tab receiver on the collection assembly, wherein the electrostatic precipitator cell is assembled by disposing the tab of the corona wire assembly into the tab receiver of the collection assembly.

In some embodiments, the air cleaner further comprises a high voltage power supply; an electrical contact on the corona wire assembly, and an electrostatic precipitator cell receiver including an electrical contact, wherein contact between the electrical contact of the corona wire assembly and the electrical contact on the electrostatic precipitator cell receiver connects the corona wire assembly to the high voltage power supply.

In some embodiments, the air cleaner further comprises a fan operable at different speeds.

In some embodiments, an amplitude of an electrical current is supplied to the corona wire assembly by the high power voltage supply which correlates to the speed of the fan.

In some embodiments, the air cleaner further comprises a high voltage power supply, an electrical contact on the collection assembly, and an electrostatic precipitator cell receiver including an electrical contact, wherein contact between the electrical contact of the collection assembly and the electrical contact on the electrostatic precipitator cell receiver connects the collection assembly to the high voltage power supply.

In alternate embodiments an electrostatic precipitator cell comprising a corona wire assembly and a collection assembly is described. The corona wire assembly comprises a first supporting member including a retaining device, a second supporting member including a retaining device, a corona wire capable of carrying a high voltage disposed between the first supporting member and the second supporting member, and a ground discharge electrode disposed between the first supporting member and the second supporting member. The collection assembly can be positioned downstream of the corona wire assembly, wherein the corona assembly is detachably installed and removed from the electrostatic collection assembly.

In some embodiments, the electrostatic precipitator cell further comprises a tab on an outer surface of the corona wire assembly, and a tab receiver on the collection assembly, wherein the electrostatic precipitator cell is assembled by disposing the tab of the corona wire assembly into the tab receiver of the collection assembly.

In some embodiments, the electrostatic precipitator cell further comprises an electrical contact on the corona wire assembly, and an electrical contact on an electrostatic precipitator cell receiver, wherein contact between the electrical contact of the corona wire assembly and the electrical contact on the electrostatic precipitator cell receiver connects the corona wire assembly to a high voltage power supply.

In some embodiments, the electrostatic precipitator cell further comprises an electrical contact on the collection assembly, and an electrical contact on the electrostatic precipitator cell receiver, wherein contact between the electrical contact of the collection assembly and the electrical contact on the electrostatic precipitator cell receiver connects the collection assembly to a high voltage power supply.

In alternate embodiments, a process of replacing a corona wire assembly is described. The process comprises providing a corona wire assembly, wherein the corona wire assembly comprises, a first supporting member including a retaining device, a second supporting member including a retaining device, a corona wire capable of carrying a high voltage disposed between the first supporting member and the second supporting member, a ground discharge electrode disposed between the first supporting member and the second supporting member, and separately installing or removing the corona wire assembly from an electrostatic precipitator.

### BRIEF DESCRIPTION OF THE DRAWINGS

The same reference number represents the same element on all drawings. It should be noted that the drawings are not necessarily to scale. The foregoing and other objects, aspects, and advantages are better understood from the following detailed description of a preferred embodiment of the invention with reference to the drawings, in which:

FIG. 1 illustrates an air cleaner that includes an electrostatic precipitator according to one embodiment;

FIG. 1A illustrates an air cleaner control according to one embodiment;

FIG. 2 illustrates an exploded view of an air cleaner according to one embodiment;

FIG. 3 illustrates a schematic of an electrostatic precipitator including a corona wire assembly and a collection assembly according to one embodiment;

FIG. 4 illustrates an exploded view of a detachable corona wire assembly according to one embodiment;

FIG. 5 illustrates an exploded view of a photo-catalytic oxidizing (PCO) assembly according to one embodiment;

FIG. 5A is an exploded view of a PCO substrate included in a PCO assembly; and

FIG. 6 illustrates a detailed view of an electrostatic precipitator cell according to one embodiment.

### DETAILED DESCRIPTION

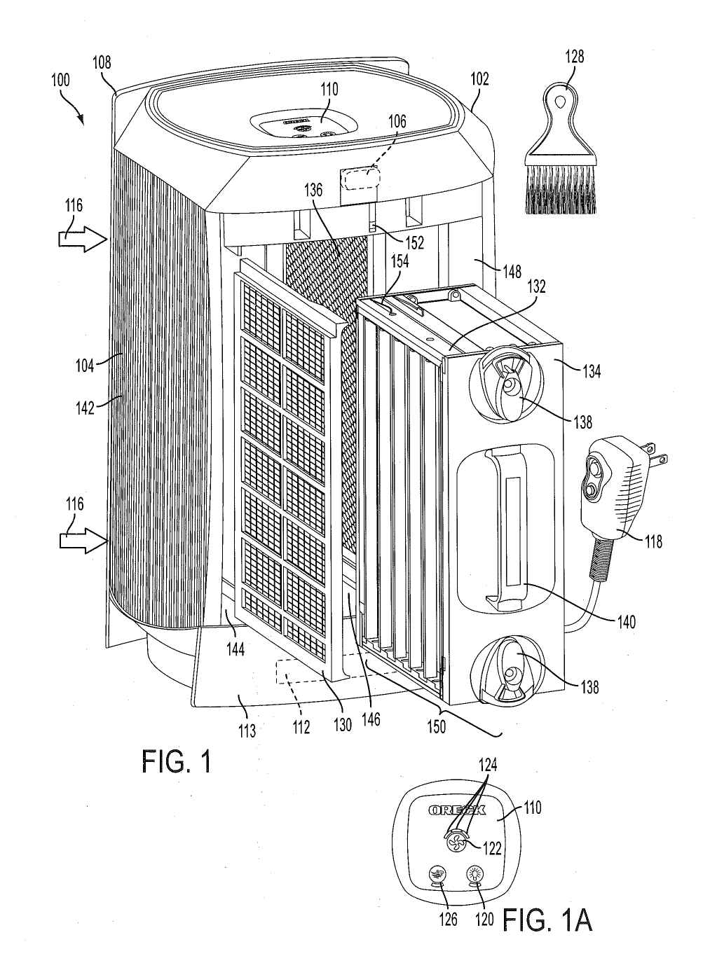

FIGS. 1-6 and the following descriptions depict specific embodiments to teach those skilled in the art how to make and use the best mode of the teachings. For the purpose of teaching these principles, some conventional aspects have been simplified or omitted. Those skilled in the art will appreciate variations from these embodiments that fall within the scope of the teachings. Those skilled in the art will also appreciate that the features described below can be combined in various ways to form multiple variations. As a result, the teachings are not limited to the specific embodiments described below, but only by the claims and their equivalents.

The present teachings provide air purifiers utilizing electrostatic precipitators including a corona wire assembly with improved longevity and cleaning features. The essential structure of the air purifier comprises an electrostatic precipitator and a corona wire assembly. The electrostatic precipitator is disposed in the air flow path of the air cleaner. The corona wire assembly is releasably or detachably retained proximate to or within the electrostatic precipitator.

As used herein, the term “filter” refers to the extraction or removal of impurities or particulates from the air. The impurities or particulates can include, but are not limited to dust, dirt, debris, volatile organic compounds, ozone, carbon dioxide, radon, carbon monoxide, pollen, spores, microbes, viruses, etc. The impurities or particulates can be macroscopic or microscopic.

FIG. 1 shows an air cleaner 100 according to an embodiment. Air cleaner 100 includes a housing 102, which can include an air inlet 104, a remote sensor 106, a sidewall 108, a control panel 110, a night light 112 and an air outlet (not shown) disposed therein or thereupon. An air inflow 116 is drawn in through air inlet 104 by fan assembly 148. Air inlet 104 is covered by a front panel grill 142. The drawn in air is substantially cleaned inside air cleaner 100, and the cleaned air is exhausted from the air outlet (not shown). Additionally, a power cord 118 can extend from housing 102. Power cord 118 can include a GFCI plug. A night light 112 disposed on housing 102 can be visible through transparent portion 113. Accessories, such as a brush 128 can be included with air cleaner 100 in order to aid in cleaning and maintaining one or more components of air cleaner 100.

Air cleaner 100 can also comprise various air filtering components. For example, in one embodiment, air cleaner includes a pre-filter 130, a corona wire assembly 132, a collection assembly 134, and a photo-catalytic oxidizing assembly 136. The combination of corona wire assembly 132 and collection assembly 134 form an electrostatic precipitator cell 150. The filter components can be disposed within housing 102 in various receptacles. For example, pre-filter 130 can be housed in a pre-filter receptacle 144. The electrostatic precipitator cell 150 can be housed in an electrostatic precipitator cell receptacle 146. The electrostatic precipitator cell 150 can include a handle 140 for easy insertion and removal of the electrostatic precipitator cell 150 from housing 102. One or more knobs 138 allow the electrostatic precipitator cell 150 to be secured into housing 102. In some embodiments, an electrostatic precipitator cell actuator 154 can be disposed on corona wire assembly 132. Without actuation of a switch (not shown) corresponding to electrostatic precipitator cell actuator 154, the power to electrostatic precipitator 150 can be disabled.

In one embodiment, knob 138 can be rotated 90 degrees and a portion of knob 138 can extend into electrostatic precipitator cell receptacle 146 to secure electrostatic precipitator cell 150 therein. A door (not shown) can enclose the filter components to complete housing 102. When the door is in place, it can actuate a door safety switch 152. In some embodiments, air cleaner 100 cannot be activated without actuating door safety 152.

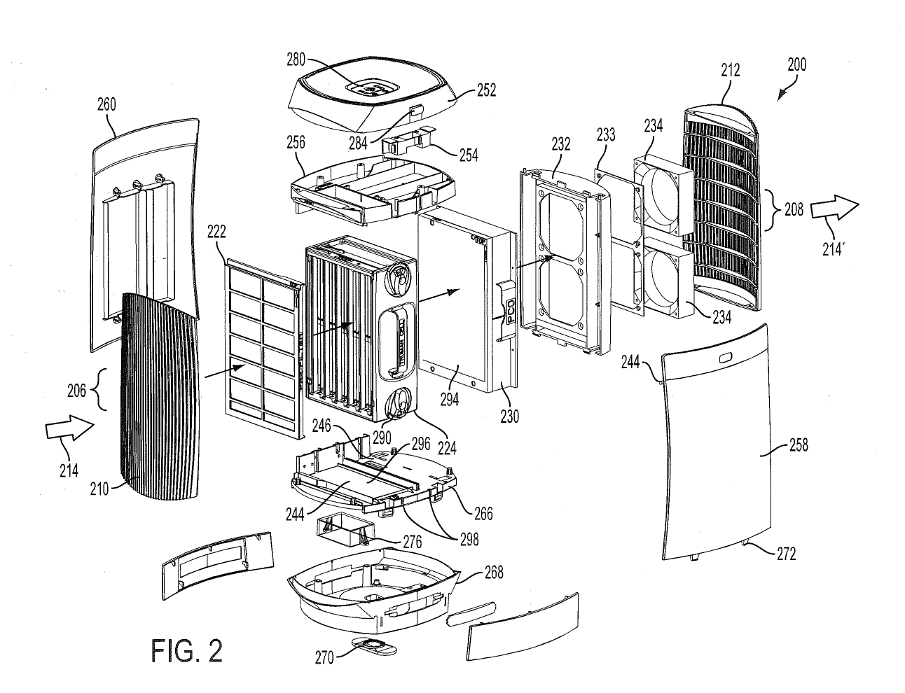

In various embodiments, air cleaner 100 can be substantially rectangular-cuboidal, substantially elliptical, substantially cuboidal, or substantially cylindrical, or combinations thereof, in shape. The exterior or outer face of housing 102 can be planar, circular, curvilinear, arcuate, or combinations thereof, in shape. Air inlet 104 can be planar, circular, curvilinear, arcuate, or combinations thereof, in shape. Air outlet (not shown) can be planar, circular, curvilinear, arcuate, or combinations thereof, in shape. In one embodiment, air inlet 104 can be arcuate and air outlet (not shown) can be arcuate in shape. Advantageously, in some embodiments, air cleaners 100 or 200 can be substantially rectangular-cuboidal in shape, only slightly taller than wide. Such dimension not only allows for increased stability of the air cleaner 100, but surprisingly allows for an electrostatic precipitator cell 224 (FIG. 2) with larger surface area of collection plates than conventional table top or floor air cleaners that utilize electrostatic precipitators.

FIG. 1A illustrates an exploded view of an air cleaner control panel 110 according to an embodiment. Air cleaner control panel 110 can include buttons for an air ionizer 126, fans 122, and/or a night light 120, for example. Control panel 110 may further optionally include indicator lights which alert the user to clean pre-filter 130, electrostatic precipitator cell 150, photo-catalytic oxidizing assembly 136, or to selectively enable or disable a UV LED assembly. Control panel 110 can also include indicator lights 124 to display a fan speed. Control panel 110 can be advantageously disposed on outer top of housing 102, thus allowing a user to easily view the indicators.

FIG. 2 shows an exploded view of air cleaner 200. Air cleaner 200 includes a housing which can comprise an outer top 250, a latch assembly 254, an inner top housing 256, a front panel 258, a rear panel 260, an air inlet grill 210, an air outlet grill 212, a bottom inner housing assembly 266, an outer bottom assembly 268, and a cord wrap cleat 270. In some embodiments, front panel 258 can be removable or can include a door. Front panel 258 can include tabs 272 that can be received by bottom inner housing assembly 266. Front panel 258 can include tabs 274 that can be received by inner top housing 256 to complete the housing. Front panel 258 can be latched by latch assembly 254, for example, by friction fit. In some embodiments, front panel 258 can use hinges and be latched. Front panel 258 opens, for example, by pushing up on front panel 258 with enough energy to disengage tabs 272 and 276. Advantageously, the removal of front panel 258 allows for easy access to all interior components for maintenance or repair. A high voltage power supply module 276 can be provided in air cleaner 200. Outer top housing 252 can include a control panel overlay 280 to receive user commands, LED lenses 282 for indicator lights, and an infrared (IR) lens 284 for receiving commands from a remote control.

The housing can define an air channel 204 extending from air inlet 206 to air outlet 208. Air channel 204 can extend substantially linearly between air inlet 206 and air outlet 208. Obstructions or obtrusions into air channel 204 are minimized. In an embodiment, air inlet 206 is substantially opposite of air outlet 208. Air inflow 214 enters air cleaner 200 through air inlet 206. A cleaning brush can be provided to clean air inlet grill 210 or air outlet grill 212.

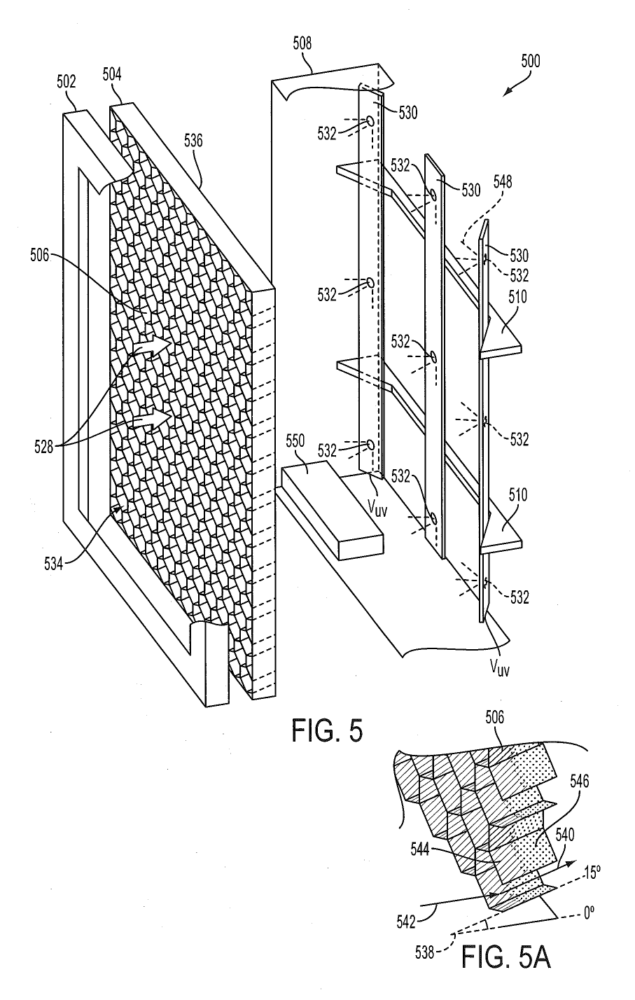

In some embodiments, air cleaner 200 can include a pre-filter 222, an electrostatic precipitator cell 224 including a collection assembly and a corona wire assembly, a photo-catalytic oxidizing assembly 230, a fan mounting panel 232, a fan gasket 233, and one or more fans 234, all disposed in air channel 204. In an embodiment, airflow 204 encounters electrostatic precipitator cell 224 after encountering pre-filter 222. In an embodiment, airflow 204 encounters photo-catalytic oxidizing assembly 230 after encountering electrostatic precipitator cell 224. In some embodiments, airflow 204 encounters a UV Light Emitting Diode (LED) assembly (shown in FIG. 5) after encountering photo-catalytic oxidizing assembly 230. In some embodiments, airflow 214 does not encounter a UV LED assembly.

Pre-filter 222, electrostatic precipitator cell 224 containing collection assembly and corona wire assembly, and photo-catalytic oxidizing assembly 230 can be independent units. Pre-filter 222, electrostatic precipitator cell 224, and photo-catalytic oxidizing assembly 230 can comprise units that are removably disposed in air channel 204. Pre-filter 222, electrostatic precipitator cell 224, and photo-catalytic oxidizing assembly 230 can comprise non-limiting combinations of removable and non-removable units that are mounted in air channel 204. Due to the independent nature of pre-filter 222, electrostatic precipitator cell 224, and photo-catalytic oxidizing assembly 230, each can be independently installed and independently removed. In addition, air cleaner 200 can be assembled into various configurations by selection of the various cleaning components for a particular application.

Each of pre-filter 222, electrostatic precipitator cell 224, and photo-catalytic oxidizing assembly 230 can be received in air cleaner 200 by some manner of receptacle(s), slot(s), rail(s), etc., and can be inserted and removed easily and quickly. In one embodiment, pre-filter 222 is received in a pre-filter receptacle 242 in air channel 204. In one embodiment, electrostatic precipitator cell 224 is received in an electrostatic precipitator cell receptacle 244. In one embodiment, photo-catalytic oxidizing assembly 230 is received in a photo-catalytic oxidizing assembly receptacle 246. One or more of the various receptacles can comprise drop-in receptacles. One or more of the various receptacles can comprise slide-in receptacles. One or more of the various receptacles can comprise receptacles that fixedly receive a component. It should be understood that other receptacle configurations are contemplated and are within the scope of the description and claims. The various receptacles can hold their respective units so that they are replaceable by a consumer or where services of a technician are required.

A tray 296 can be included in electrostatic precipitator cell receptacle 244 to collect and pool any excess water during routine cleaning of electrostatic precipitator cell 224. Tray 296 collects and holds the water until it evaporates, protecting any sensitive electronic circuitry and/or high voltage power supply 276 that may be in the air cleaner.

Pre-filter 222 can comprise a fiber, a mesh, a cloth, a paper, a woven filter, or a combination thereof. Pre-filter 222 can comprise a High Efficiency Particulate Air (HEPA) filter (typically able to remove 99.7% of particulates to about 0.3 micron in diameter), an allergen air filter, an electrostatic air filter, a charcoal filter, an anti-microbial filter, or other filtering media known in the art. In addition, pre-filter 222 can be treated with a germicide, fungicide, bactericide, insecticide, etc. in order to kill germs, mold, bacteria, viruses, and other airborne living organisms (including microorganisms). Pre-filter 222 can have length L, height H, and width W. Pre-filter 222 can be capable of filtering impurities or particulates with an average diameter of at least 0.1, 0.3, 0.5, 1.0, 5.0, 10.0, 100 microns or greater, including impurities or particulates with an average diameter of 0.001, 0.01, 0.1, 1.0 millimeters or greater.

### Electrostatic Precipitator

Electrostatic precipitator cell 224 removes dirt and debris from the airflow by electrostatic attraction. An electrostatic precipitator cell operates by creating a high voltage electrical field. Dirt and debris in the air become ionized when they are brought into the electrical field by the airflow. Charged electrodes in an electrostatic precipitator cell air cleaner, such as positive and negative plates or positive and grounded plates, attract the ionized dirt and debris. Because the electrostatic precipitator cell comprises electrodes or plates through which airflow can easily and quickly pass; only a low amount of energy is required to generate the airflow. As a result, foreign objects in the air can be removed efficiently and effectively. Electrostatic precipitator cells can comprise corona wires or corona plates for ionizing the air particles. Electrostatic precipitator cell 224 can have length L, height H, and width W. Electrostatic precipitator cell 224 can be capable of filtering impurities or particulates with an average diameter of at least 0.1, 0.3, 0.5, 1.0, 5.0, 10.0, 100 microns or greater including impurities or particulates with an average diameter of 0.001, 0.01, 0.1, 1.0 millimeters or greater.

Electrostatic precipitator cell 224 can further comprise one or more highly visible knobs 290. Knobs 290 can be turned so as to lock electrostatic precipitator cell 224 into air cleaner 200. Electrostatic precipitator cell 224 can comprise a handle 294 that can be used to easily grasp electrostatic precipitator cell 224 for installation and removal from electrostatic precipitator receptacle 246 for cleaning or replacement.

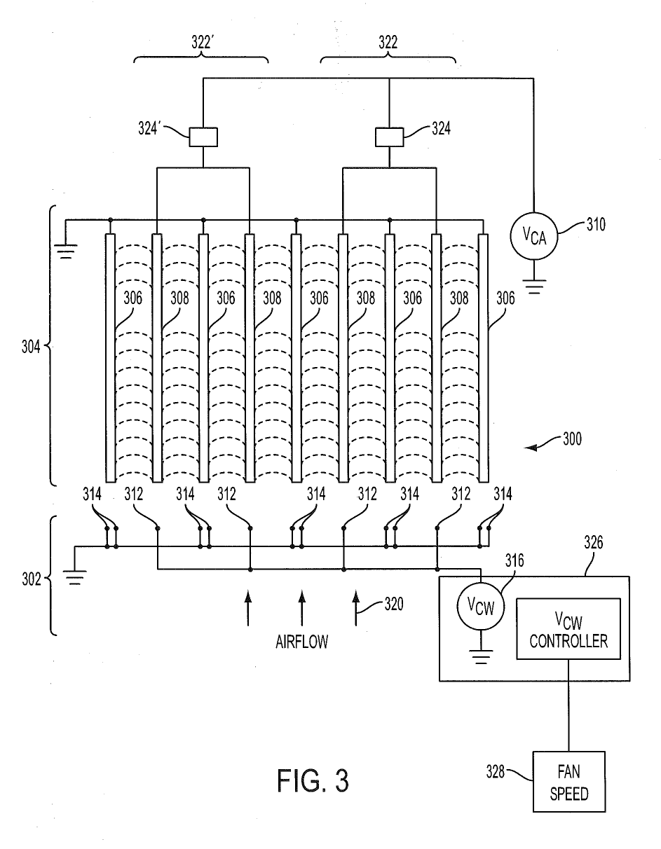

FIG. 3 shows an electrostatic precipitator cell 300 with corona wire assembly 302 and collection assembly 304 according to one embodiment. Collection assembly 304 includes one or more collection assembly charge plates 308, one or more collection assembly ground plates 306, and a first voltage source 310. The corona wire assembly 302 includes one or more corona charge elements 312, two or more corona ground elements 314, and a second voltage source 316. The corona ground elements 314 can be arranged in a substantially parallel orientation and the corona charge elements 312 can be substantially centered between adjacent corona ground elements 314. The corona charge elements 312 can be substantially equidistant from adjacent corona ground elements 314 and the corona charge elements 312 can be substantially laterally centered on the adjacent corona ground elements 314.

According to one embodiment, in operation, a first voltage potential V_{CA} is placed across the electrostatic collection assembly 304 by the first voltage source 310, creating one or more first electrical fields between one or more collection assembly charge plates 308 and one or more collection assembly ground plates 306. In addition, a second voltage potential V_{CW} is placed across the corona wire assembly 302 by the second voltage source 316, creating a second electrical field between one or more corona charge elements 312 and two or more corona ground elements 314. Therefore, an airflow 320 traveling through the electrostatic precipitator cell 300 (from bottom to top in the figure) is ionized by the second voltage potential V_{CW} as airflow 320 passes through the corona wire assembly 302. As a consequence, dirt and debris entrained in airflow 320 are charged (typically a positive charge) and the charged dirt and debris are attracted to the one or more collection assembly ground plates 306. Airflow 320, now substantially without the dirt and debris, exits electrostatic precipitator 300 and is exhausted from the electrostatic precipitator 300 in a substantially cleaned condition.

In some embodiments, the electrostatic precipitator 300 is provided with a voltage sufficient to ionize and collect air particulates. In some embodiments, the voltage to the electrostatic precipitator ranges from about 8000 volts to about 3000 volts. In a preferred embodiment, the voltage to the electrostatic precipitator 300 ranges from about 3900 volts to about 4000 volts. The second voltage source 316 can provide the same or different voltage potential than the first voltage source 310 (i.e., V_{CA}=V_{CW} or V_{CA}≠V_{CW}). In one embodiment, the second voltage source 316 provides a higher voltage potential than the first voltage source 310 (i.e., V_{CW}>V_{CA}). For example, the second voltage source 316 can provide about twice the voltage level as the first voltage source 310, such as about 8,000 volts versus about 4,000 volts in one embodiment. However, it should be understood that the second voltage potential V_{CA} can comprise other voltage levels.

It should be understood that the corona wire assembly 302 can be formed of any number of corona ground elements 314 and corona charge elements 312. The corona ground elements 314 can be positioned in a substantially coplanar alignment with the collection assembly ground plates 306 of collection assembly 304 while the corona charge elements 312 can be positioned in a substantially coplanar alignment with the collection assembly charge plates 308. Each corona charge element 312 can be substantially centered between two opposing corona ground elements 314. A corona charge element 312 in one embodiment can be substantially vertically centered in the figure with regard to the corona ground elements 314 in order to optimize the produced electrical field.

In operation, the corona wire assembly 302 forms electrical fields between the corona charge elements 312 and the corresponding pair of corona ground elements 314. The dashed lines in the figure approximately represent these electrical fields, and illustrate how the electrical field lines are substantially perpendicular to the airflow and are substantially uniform between the corona charge elements 312 and the corresponding corona ground elements 314. The electrical field of the corona wire assembly 302 can ionize the airflow before the airflow travels through the collection assembly 304. In addition, the second voltage potential V_{CW} placed on the corona wire assembly 302 by second voltage source 316 can be independent of the first voltage potential V_{CA} placed on the collection assembly 304 by the first voltage source 310. Consequently, the second voltage potential V_{CW} can be greater or much greater than the first voltage potential V_{CA}.

In some embodiments, collection assembly charge elements 308 can be grouped into banks 322 and 322′ of collection assembly charge elements. Each bank 322 and 322′ can be connected to a first voltage source 310 with voltage potential V_{CA}. A voltage isolator 324 and 324′ can electrically isolate bank 322 from bank 322′. In some embodiments, voltage isolators 324 and 324′ can comprise one or more resistors. The resistors can be 1 Megaohms or greater.

V_{CW} provided by second voltage source 316 can be varied by a controller 326. In some embodiments, controller 326 can sense a fan speed 328. Controller 326 can request a higher V_{CW} for higher fan speeds. In some embodiments, controller 326 can request a decreased V_{CW} for lower fan speeds. Controller 326 can use a pulse width modulation (PWM) circuit to determine the duty cycle of a fan. The duty cycle can determine the voltage requested from second voltage source 316.

### Corona Wire Assembly

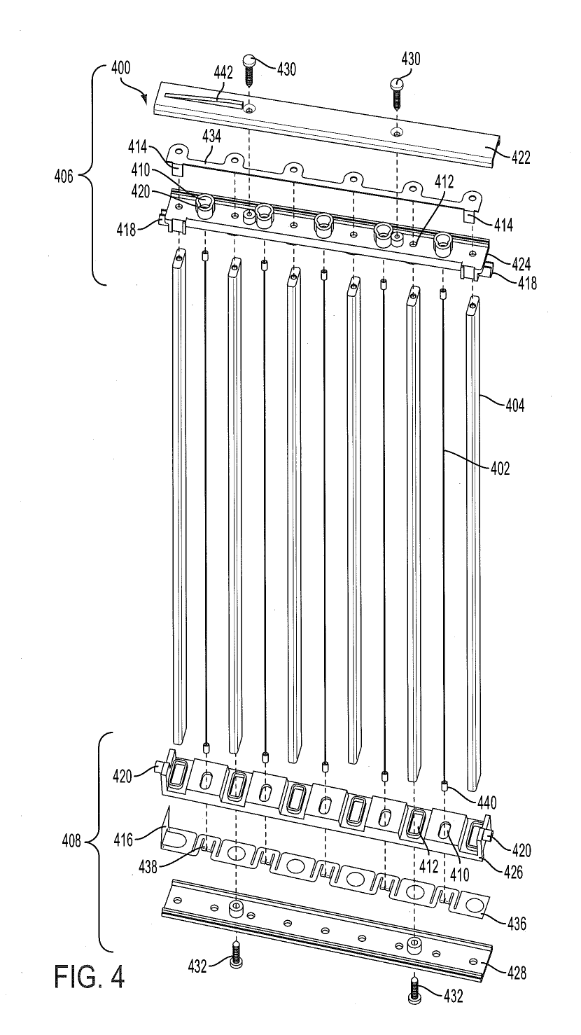

FIG. 4 shows a corona wire assembly 400 according to one embodiment. The corona wire assembly 400 includes one or more corona charge elements 402, two or more corona ground elements 404, first supporting member 406, and second supporting member 408. The corona ground elements 404 can be arranged in a substantially parallel orientation and the corona charge elements 402 can be substantially centered between adjacent corona ground elements 404. The corona charge elements 402 can be substantially equidistant from adjacent corona ground elements 404 and the corona charge elements 402 can be substantially laterally centered on the adjacent corona ground elements 404.

First supporting member 406 includes corona charge element apertures for receiving corona ground elements 404 and corona charge elements 402. For example, first supporting member 406 includes one or more corona charge element receiving apertures 410 and corona ground element receiving apertures 412. The shape of the apertures may be substantially the same as the corona ground elements 404 or corona charge elements 402, and may be substantially circular, oval, rectangular, square, etc. Corona charge element receiving aperture 410 of first supporting member 406 can also include retaining slot 420. The distal ends of corona charge elements 402 are thus retained in retaining slot 420.

Second supporting member 408 includes corona charge element apertures for receiving corona ground elements 404 and corona charge elements 402. For example, second supporting member 408 includes one or more corona charge element receiving apertures 410 and corona ground element receiving apertures 412. The shape of the apertures may be substantially the same as the corona ground elements 404 or corona charge elements 402, and may be substantially circular, oval, rectangular, square, etc. Alternatively, the shape of the apertures may be substantially different from the corona ground elements 404 or corona charge elements 402, and may be substantially circular, oval, rectangular, square, etc.

First supporting member 406 may include one or more electrical contacts 414 on an outer planar surface of first supporting member 406 for conducting electrical current to a collection assembly (not shown). Second supporting member 408 may include one or more electrical contacts 416 on an outer planar surface of second supporting member 408 for conducting electrical current from the air cleaner (not shown).

First supporting member 406 may include one or more retaining devices 418 on an outer planar surface of first supporting member 406 for retaining the first supporting member to a collection assembly (not shown). Second supporting member 408 may include one or more retaining devices 420 on an outer planar surface of second supporting member 408 for retaining the second supporting member 408 to a collection assembly (not shown). Retaining devices 418 and/or 420 may be projections, tabs, fins, ears, etc.

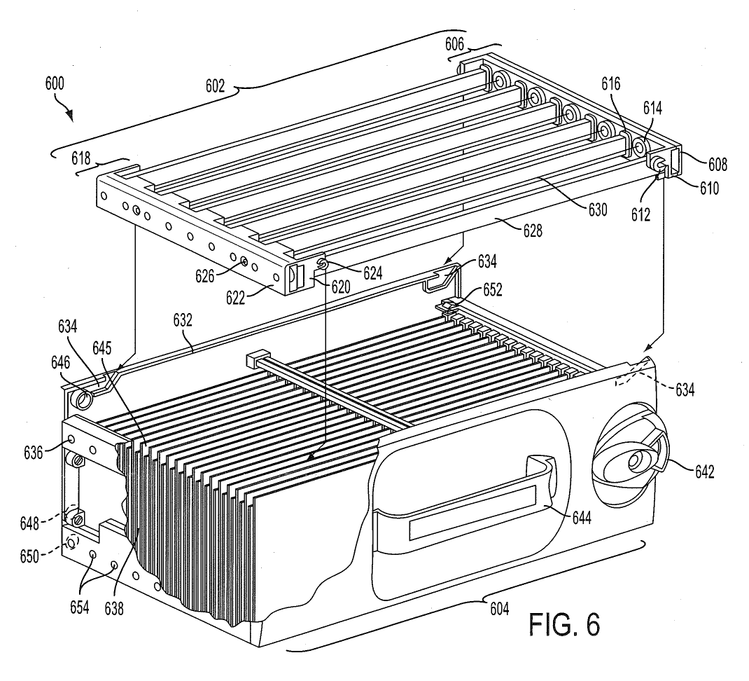

Retaining devices 418 and 420 cooperate with the collection assembly (not shown) in order to hold the corona wire assembly 400 to a collection assembly (see FIG. 6). The retaining devices fit into the collection assembly (not shown), and can be held in a collection assembly by any manner of slots, ears, springs, fasteners, heat staking, welds, etc. In one embodiment, retaining devices 418 and 420 are tabs and can be inserted into corresponding receiving slots (shown in FIG. 6) of a collection assembly.

First supporting member 406 can include upper portion 422 and lower portion 424. Second supporting member 408 can include upper portion 426 and lower portion 428. The upper and lower portions of first supporting member (422 and 424, respectively) can be assembled to form first supporting member 408 using any suitable manner, include fastener 430. The upper and lower portions of second supporting member (426 and 428, respectively) can be assembled to form second supporting member 408 using any suitable manner, include fastener 432.

First supporting member 406 can house electrical contact strip 434 which connects corona ground elements 404. A corona ground element 404 can be secured to first supporting member lower housing 424 and electrical contact strip 434 via fasteners 430. Second supporting member 408 can house electrical contact strip 436 which connects corona charge elements 402 via electrical contact 416. A corona ground element 404 can be secured to second supporting member upper housing 426 via fasteners 432. A distal end of corona charge element 402 can be secured to second supporting member upper housing 420 via retention slots 438 in electrical contact strip 436.

The electrical contact strip 436 in one embodiment is formed of a flexible, electrically conductive material or at least partially of an electrically conductive material. For example, the electrical contact strip 436 can be formed of a metal material or a metal alloy. Alternatively, the electrical contact strip 436 can be formed of a flexible material that includes an electrically conductive layer, such as a metal plating layer. However, it should be understood that the electrical contact strip 436 can be formed of any suitable material, and various material compositions are within the scope of the description and claims.

Referring again to FIG. 2, electrostatic precipitator cell 224 is capable of generating ozone as a by-product of ionization. The ionization transforms stable (O₂) molecules in the air into ozone molecules (O₃). Subsequently, the third oxygen atom of the ozone molecules enters into destructive reactions with contaminants in the vicinity by oxidizing compounds into which they come into contact. The oxidation can add oxygen molecules to these contacted compounds during the oxidation reaction. Ozone is a powerful oxidizer because it is not a stable molecule. Ozone molecules spontaneously return to a stable molecular state by releasing their third oxygen atoms. However, the spontaneous breakdown of ozone does not occur immediately, and substantial amounts of ozone can linger in the airstreams for some time. One of the great advantages of ozone is that it is not selective in the reactions it initiates. Ozone neutralizes harmful volatile organic compounds (VOCs) by oxidizing them. Ozone also destroys pathogens (microorganisms) either by reducing or destroying them or by cell lysing or oxidation. Another beneficial effect of ozone is that ozone treatment of the air can remove some troublesome odors.

### Collection Assembly

As shown in FIG. 3, collection assembly 304 can have at least one voltage potential placed across the collection assembly creating one or more electrical fields. In one embodiment, a single voltage potential creates an electrical field over the entire collection assembly. In some embodiments, banks 322 and 322′ are in series. In alternate embodiments, banks 322 and 322′ are in parallel. Preferably, banks 322 and 322′ are in parallel. The separated banks deter large arcing between the collection assembly charge plates and ground plates.

In some embodiments, the individual banks 322 and 322′ all have the same voltage potentials. In some embodiments, the individual banks 322 and 322′ all have different voltage potentials. It should be recognized that it may be beneficial to have some voltage potentials be equal to others, but different than the rest. A variety of combinations of voltage potentials is possible, and can be determined by a skilled artisan, depending upon the needs of the unit.

As illustrated in FIG. 3, collection assembly 304 can include between about 2 and 20 collection assembly charge plates 308 and between about 2 and 20 collection assembly ground plates 306 within any individual collection bank. In a preferred embodiment, collection assembly 304 can include about 10 collection assembly charge plates 308 and about 10 collection assembly ground plates 306 within a single collection bank. As a result, collection assembly 304 preferably can have as many as 40 collection assembly ground plates 306 and 40 collection assembly charge plates 308. The surface area of one side of one collection assembly charge plate 308 or collection assembly ground plate 306 is about 0.0204 m². In a preferred embodiment, there can be about 41 collection assembly charge plates 308 or collection assembly ground plates 306 (e.g., 82 collection faces) which results in a collection surface area of about 1.67 m2 (82*0.0204 m²=1.67 m²). This surface area increases the cleaning efficiency of the air cleaner surprisingly without requiring any additional current or voltage requirements for performance.

Additionally, the height between collection assembly charge plates 308 and collection assembly ground plates 306 must be sufficient enough to allow adequate ionization of air particulates without increasing pressure within the unit, and cannot be so close as to promote unnecessary arcing of the unit. The distance between collection assembly charge plates 308 and collection assembly ground plates 306 can range from about 3 mm to about 5 mm. Preferably, the distance between collection assembly charge plates 308 and collection assembly ground plates 306 is about 4 mm. It was identified that this distance allows for maximum air flow, with minimum air pressure increase and arcing between the charge and ground plates.

As shown in FIG. 2, electrostatic precipitator cell 224 can also include one or more knobs 290. In order to remove electrostatic precipitator cell 224 from air cleaner 200, both knobs 290 must be released. Knobs 290 can be made from the same material as the electrostatic precipitator cell, including non-conductive materials. While a single knob 290 may be sufficient to secure the electrostatic precipitator cell 224 to the electrostatic precipitator receptacle 244, multiple knobs 290 increase the security of the electrostatic precipitator cell 224 within air cleaner 200, and ensure proper contact between electrical contacts (not shown) on the electrostatic precipitator cell 224 with air cleaner 200. As such, the electrostatic precipitator cell, having a collection assembly and corona wire assembly, functions properly and most efficiently.

FIG. 6 also shows an electrostatic precipitator cell 600 according to one embodiment. Electrostatic precipitator cell 600 can include corona wire assembly 602 and collection assembly 604. Corona wire assembly 602 can include a first supporting member 606 and a second supporting member 618. First supporting member 606 can include first supporting member upper housing 608 and first supporting member lower housing 610. Second supporting member 618 can include second supporting member upper housing 620 and second supporting member lower housing 622. In some embodiments, the various portions of first supporting member 606 or the second supporting member 618 are secured via fasteners 626. Secured between first supporting member 606 and second supporting member 618 are corona wire ground elements 628 and corona wires 630.

Collection assembly 604 can include electrostatic precipitator cell frame 632. Electrostatic precipitator cell 600 can include knobs 642 to secure the electrostatic precipitator 600 into an air cleaner housing (not shown). Additionally, electrostatic precipitator 600 can include handle 644 in order to easily insert and remove the electrostatic precipitator cell 600 from an air cleaner housing (not shown).

Collection assembly 604 preferably can have as many as about 40 collection assembly ground plates 640 and about 40 collection assembly charge plates 638. In a preferred embodiment, collection assembly 640 has 21 collection assembly ground plates 640 and about 20 collection assembly charge plates 638. The result of the increased amount of collection assembly charge plates 638 and collection assembly ground plates 640 results in a total surface area of 1.67 m².

Additionally, the height between collection assembly charge plates 638 and collection assembly ground plates 640 must be sufficient enough to allow adequate ionization of air particulates without increasing pressure within the unit, and cannot be so close as to promote unnecessary arcing of the unit. The distance between collection assembly charge plates 638 and collection assembly ground plates 640 can range from about 3 mm to about 5 mm. Preferably, the distance between collection assembly charge plates 638 and collection assembly ground plates 640 is about 4 mm. It was identified that this distance allows for maximum collection surface area and air flow with a minimum air pressure increase and arcing between electrodes. Thus, the electrostatic precipitator cell described herein has an increased particulate collection efficiency compared to prior art models because the air cleaner has an increased surface area—both in dimension of plates and number of plates.

As mentioned above, electrostatic precipitator cell 600 can include corona wire assembly 602 and collection assembly 604. Corona wire assembly 602 can include retainer devices 612 and 624, which when inserted into corresponding receiving slots 634 in collection assembly 604 can secure corona wire assembly 602 to collection assembly 604. Retainer devices 612 are offset from the center of the outer side surface of first supporting member 606 and second supporting member 618. As a result, retainer devices 612 on corona wire assembly 602 and corresponding receiving slots 634 in collection assembly 604 ensure that the corona wire assembly 602 is properly inserted into the collection assembly. When the corona wire assembly 602 is properly inserted into collection assembly 602, electrical contacts (not shown) on the first supporting member 608 of the corona wire element 602 contact electrical contact 652 on the collection assembly 602 to ground the collection assembly 604. Attempts to insert the retaining devices 612 in the wrong orientation will not allow the corona wire assembly 602 to be seated into the collection assembly 604, thus connection between electrical contact 652 on the first supporting member 608 will not contact electrical contact 652 on collection assembly 604, and the electrostatic precipitator 600 will not function.

Electrostatic precipitator cell frame 632 has several electrical contact apertures 646, 648 and 650, which permit electrical contact between the electrostatic precipitator cell 600 and a high voltage power supply (not shown) in the air cleaner. The electrical contact apertures 646, 648 and 650 can be for the corona wire assembly 602 alone, for the collection assembly alone 604, or for both the collection assembly 604 and the corona wire assembly 602.

A “dry mode” operating circuit can be configured to dry the electrostatic precipitator cell 600 after cleaning. While in “dry mode” air cleaner fans can operate but no power is supplied to the electrostatic precipitator cell 600 (discussed further below). Weep holes 636 and 654 allow excess water from the collection assembly charge plates 638 and collection assembly ground plates 640 to escape from the electrostatic precipitator cell 600. A water reservoir (not shown) can be included in the air cleaner housing as a section of the electrostatic precipitator receptacle to collect and pool any excess water. The water reservoir collects and holds the water until it evaporates, protecting any sensitive electronic circuitry and high voltage power supply that may be in the air cleaner.

### Photo-Catalytic Oxidizing Assembly

As illustrated in FIG. 5, photo-catalytic oxidizing assembly 500 can comprise a photo-catalytic oxidizing assembly frame 502 adapted to support a photo-catalytic oxidizing assembly substrate 504. Air flow 528 can travel through a plurality of air passages 506 from a first outer surface 534 of photo-catalytic oxidizing assembly substrate 504 to a second outer surface 536 of PCO substrate 504. In some embodiments, photo-catalytic oxidizing assembly 500 can comprise metal. Photo-catalytic oxidizing assembly 500 can comprise any manner of desired filter element. In one embodiment, PCO substrate 504 can comprise a fiber, a mesh, a woven filter, a paper, a cloth, a porous material, or a porous structure, for example. Photo-catalytic oxidizing assembly 500 can comprise a HEPA filter, an allergen air filter, an electrostatic air filter, a charcoal filter, or an anti-microbial filter, as previously described. Photo-catalytic oxidizing assembly 500 can be treated with a germicide, fungicide, bactericide, insecticide, etc. Photo-catalytic oxidizing assembly 500 can have length L, height H, and width W. Photo-catalytic oxidizing assembly 500 can be capable of filtering impurities or particulates with an average diameter of at least 0.1, 0.3, 0.5, 1.0, 5.0, 10.0, 100 microns or greater, including impurities or particulates with an average diameter of 0.001, 0.01, 0.1, 1.0 millimeters or greater.

In certain embodiments, photo-catalytic oxidizing assembly 500 can include one or more of an odor filtration, VOC and/or ozone filtration element. Photo-catalytic oxidizing assembly 500 can use a catalyzing compound for generating and removing ozone. Photo-catalytic oxidizing assembly 500 can use a catalyzing compound for removing VOCs. Photo-catalytic oxidizing assembly 500 includes air passages 506 which filter odors, VOCs or ozone. Air passages 506 may be formed by series of substantially serpentine sheets interspersed with substantially planar divider sheets that can comprise any suitable materials and can be formed to a desired shape and size. In some embodiments, air passages 506 can include any cross-sectional shape, including octagonal, hexagonal, circular, irregular, etc. In one embodiment, PCO substrate 504 is formed of a metal matrix, such as an aluminum matrix, for example. The aluminum matrix allows some compression wherein the aluminum matrix can accommodate some shaping. In another embodiment, PCO substrate 504 is formed of a ceramic/paper matrix. The ceramic/paper matrix advantageously can be impregnated with a higher concentration of removal components than a metal matrix.

In some embodiments, air passages 506 can be parallel to (or co-linear with) the airflow 528. In other words, air passages are zero degrees to a horizontal airflow. In some embodiments, air passages can be angled down between zero and up to 90 degrees from a horizontal airflow. In a preferred embodiment, air passages are angled 15 degrees down. Surprisingly, the downward angle permits the UV light to penetrate further and blocks the UVA from being visible to users. As such, the air cleaner unit is more efficient at ozone and VOC removal, and safer to use than conventional air cleaners.

PCO substrate 504 (such as a three-dimensional matrix, for example) can include a PCO layer deposited on substrate 504. The POC layer is activated by UV light supplied by, for example, a UV LED assembly (FIG. 5). PCO layer may react with water vapor from the air to release hydroxyl radicals. Photo-catalytic oxidation utilizes ultraviolet or near-ultraviolet radiation to promote electrons from the valence band into the conduction band of a metal oxide semiconductor. Decomposition of VOCs takes place through reactions with molecular oxygen or through reactions with hydroxyl radicals and super-oxide ions formed after the initial production of highly reactive electron and whole pairs. Thus, a catalyst layer extends the life of photo-catalytic oxidizing assembly 500. For example, photo-catalytic oxidizing assembly 500 can comprise an ozone catalyst layer deposited on PCO substrate 504. In this embodiment, photo-catalytic oxidizing assembly 500 can remove a significant amount of the ozone in the airflow. Photo-catalytic oxidizing assembly 500 can also include a VOC decomposition layer deposited on substrate 504. As a result, photo-catalytic oxidizing assembly 500 removes VOCs in an airflow by a process of catalysis. Photo-catalytic oxidizing assembly 500 can further remove odors from the airflow. The odor removal can be by catalysis or adsorption. Because photo-catalytic oxidizing assembly 500 substantially removes ozone, VOCs, and odors from an airflow, an air cleaner can remove a very high proportion of contaminants that can cause odors, irritation, or health problems. In addition, VOCs are substantially removed from the air, removing the health risks that they represent. In some embodiments, a portion of substrate 504 is not covered by a PCO layer. The portion of substrate 504 that includes a PCO layer can be illuminated by a UV LED (532). The illumination from UV LED 532 can catalyze the photo-catalytic oxidation reaction.

The ozone decomposing catalyst layer can be deposited over the entire substrate, or a portion thereof. The ozone decomposing catalyst layer can be deposited over 10, 20, 30, 40, 50, 60, 70, 80, 90, 95, or 100 percent of the entire substrate of photo-catalytic oxidizing assembly 500. The VOC decomposing catalyst layer can be deposited over the entire substrate, or a portion thereof. The VOC decomposing catalyst layer can be deposited over 10, 20, 30, 40, 50, 60, 70, 80, 90, 95, or 100 percent of the entire substrate of photo-catalytic oxidizing assembly 500. The PCO catalyst layer can be deposited over a portion of the surface area of the entire substrate. The PCO catalyst layer can be deposited over 10, 20, 30, 40, 50, 60, 70, 80, 90, or 95 percent of the entire substrate of a photo-catalytic oxidizing assembly. In an embodiment, the PCO catalyst layer can be deposited over 50 percent of the surface of the substrate. The remaining 50 percent of the surface of the substrate can comprise the VOC decomposing catalyst layer. The catalyst layers can be applied simultaneously or sequentially. The catalyst layers can be applied in any order. In some embodiments, the PCO catalyst is the outside layer for a portion of the surface area of the substrate, for example, 50% of the surface area. In some embodiments, the ozone removal layer can be applied prior to the VOC removal layer that is applied prior to the PCO catalyst layer. In some embodiments, the VOC removal layer can be applied prior to an application of an ozone removal layer that is applied prior to the PCO catalyst layer.

For example, photo-catalytic oxidizing assembly 500 can include some manner of carbon, zeolite, or potassium permanganate filter or filter component for odor removal. In addition, photo-catalytic oxidizing assembly 500 can include an odor emitting element. For example, photo-catalytic oxidizing assembly 500 can include a perfume packet or cartridge portion that emits a desired perfume (or other scent). Therefore, photo-catalytic oxidizing assembly 500 can comprise one or more of a mechanical filter element, an odor filtration element, and an odor emitting element.

Additionally, in one embodiment, an ozone decomposing material can include a metal oxide material deposited on substrate 504. Ozone reacts with the metal oxide and decomposes in a catalytic reaction. In one embodiment, an ozone decomposing material can comprise manganese oxide (MnO₂). In another embodiment, an ozone decomposing material can comprise titanium dioxide (TiO₂). However, it should be understood that an ozone decomposing material can comprise any manner of suitable metal oxide, such as, but not limited to Al₂O₃, SiO₂, TiO₂, Fe₂O₃, and ZnO. In another embodiment, the ozone decomposing catalytic material includes two or more catalytic materials for ozone removal.

In some embodiments, photo-catalytic oxidizing assembly 500 can comprise a single VOC removal material. In another embodiment, the VOC catalytic material includes two or more catalytic materials for VOC removal. Photo-catalytic oxidizing assembly 500 can comprise a MnO₂ material. However, it should be understood that the VOC removal material can comprise any manner of suitable metal oxide, such as, but not limited to Al₂O₃, MnO₂, SiO₂, TiO₂, Fe₂O₃, and ZnO. Thus, photo-catalytic oxidizing assembly 500 may optionally include a single removal element that simultaneously removes ozone, VOCs, and odors from the airflow.

For example, FIG. 5A shows an exploded view of a PCO substrate 504. Air passages 506 of PCO substrate 504 can include a first catalyst, e.g. a PCO catalyst layer 546. The first catalyst can cover a portion of the sidewalls comprising air passage 506, e.g., about 70% of the surface area of air passage 506. Air passages 506 of PCO substrate 504 can also include a second catalyst, e.g., a non PCO catalyst layer 544. The second catalyst can cover a portion of the sidewalls comprising air passage 506, e.g., about 30% of the surface area of air passage 506. Air passages 506 are co-linear with a direction 540. The primary direction of travel for air flow 528 encountering substrate 506 can be co-linear with a direction 542. As such, air flow 528 can travel into air passages 506 in direction 542 and exit air passages 506 in direction 540. Direction 540 and 542 can intersect at an angle 538. For example, when an air cleaner is placed on the ground for use, angle 538 of about 15 degrees is sufficient to block or limit viewing of the UV light source by a user in a sitting or standing position. The 15 degree angle is sufficient to reduce the angle of viewing of the UV light during normal operation of the air cleaner.

### UV-Light Assembly

As shown in FIG. 5, a UV LED assembly 530 can radiate UV light on PCO element 504 using a UV LED 532. UV LED 532 can comprise a plurality of UV LEDs. One or more of UV LED assembly 530 can be disposed in an air cleaner. The quantity of UV LEDs 532 and/or UV LED assemblies 530 can be optimized to provide the correct intensity of illumination 548 to PCO element 504. In some embodiments, UV LED 532 can provide light in the UV-A spectrum.

The UV illumination can be supplied by UV LED assembly 530, and may be configured to irradiate a variety of infestation agents that may be present within airflow. These agents are capable of passing through a pre-filter, electrostatic precipitator, and photo-catalytic oxidizing assembly 500, or alternatively generate ozone. In general, UV light wavelengths are considered to have a wavelength that is about 100 to about 400 nm. UV light is considered beyond the range of visible light. The UV light waves can have wavelengths of 400-320 nm, 320-280 nm, or 280-100 nm, and are normally referred to as UV-A, UV-B, and UV-C waves respectively. Preferably, the UV light waves are UV-A with wavelengths of 400-320 nm. The dosage of UV light (in terms of millijoules per square centimeter or “mJ/cm”) is a product of light intensity (or irradiance) and exposure time. Intensity is measured in microwatts per square centimeter (μW/cm²), and time is measured in seconds. The light source may be, for example, a generally U-shaped, 35-watt, high-output, no-ozone bulb (not shown) suitable for radiating light in the selected UV wavelength range of light, or a series of LED UV lights 532 as seen in FIG. 5. In some embodiments, a single linear bulb or multiple linear or shaped bulbs can be employed. If UV LEDs are used, the LEDs may comprise 1, 2, 3, 4, 5, 6, or more UV LEDs. The lights may be configured in series or in parallel. The loss of power to one bulb may or may not be sufficient to shut down the remaining bulbs.

FIG. 5 also illustrates a UV LED assembly 530 that can include multiple LEDs 532. One or more circuit boards (not shown) can be electrically connected to a power distributor 550 to provide one or more UV LEDs 532 with a voltage potential Vuv. UV illumination 548 from UV LED assembly 530 can be contained wholly within photo-catalytic oxidizing assembly housing frame 508. UV light assemblies can be secured to photo-catalytic oxidizing assembly housing frame 508 via LED supports 510. LED supports 510 can be shaped to direct UV light onto PCO substrate 504 sufficiently. LED supports 510 can have an angled portion to facilitate and direct UV light from UV light assembly 530 onto PCO substrate 504.

In some embodiments, UV LED assembly 530 provides a high-density distribution of UV LEDs 532. In some embodiments, UV LEDs 532 can comprise low intensity UV LEDs. A high-density distribution can increase the intensity of the illumination provided by UV LEDs 532. In some embodiments, UV LEDs 532 can provide light in the UV-A spectrum.

In alternate embodiments, UV LED assembly 530 provides a sparse or low-density distribution of UV LEDs 532. In some embodiments, UV LEDs 532 can comprise high intensity UV LEDs. A sparse distribution can provide a desired intensity of UV illumination without using a large number of UV LEDs 532. In some embodiments, UV LEDs 532 can provide light in the UV-A spectrum.

### Air Path

As seen in FIG. 2, air inlet 206 can comprise a substantially rectangular inlet, wherein air inflow 214 travels substantially linearly into air inlet 206, through grille 210 and through pre-filter 222. Substantially cleaned air outflow 214′ can travel substantially linearly outward from air outlet 208 through grille 210. Substantially cleaned air outflow 214′ can travel substantially horizontally. Grille 210 or 212 can include louvers, slats, bars, mesh, or wire. The louvers, slats, bars, mesh, or wire of grille 210 or 212 can be permanent, or replaceable or combinations thereof. The louvers, slats, bars, mesh, or wire can be fixed or stationary, or combinations thereof, and are capable of directing the airflow into air channel 204 through air inlet 206, and out of air outlet 208. The direction of airflow out of air outlet 208 can be 180, 160, 140, 120, 90, 60, 45, 30, or less degree away from air cleaner 200.

As shown in FIG. 2, fans 234 can be controlled to create and regulate the airflow. Fans 234 can include variable speed settings including low, medium and high speeds. Fan speed can direct the amount of current directed to corona wire assembly 304. For example, the lower the fan speed, the lower the current sent to corona wire assembly 304. Current to the corona wire assembly 304 can be limited via pulse width modulation signals through a power supply. Table 1 shows a preferred example of power parameters sent to corona wire assembly 304 as determined by fan speed.

TABLE 1

| | Plate | | Wire |
|---|---|---|---|
| Fan | Voltage | Wire Current | Voltage |
| Speed | (kV) | (uA) | (kV) |
| Low | 3.9 | 130 | 5.9 |
| Med | 3.9 | 175 | 6.1 |
| High | 3.9 | 250 | 6.3 |

As a result, the ozone generation by the corona wire assembly 304 is reduced with lower fan speeds. Also, this runs the corona wire assembly 304 at a lower current density, which extends the life of the corona charge elements (wires) 312 within the corona wire assembly 304. Fans 234 can be removably or permanently affixed to fan mounting panel 232. Further, all fans 234 are activated when power to fans is provided.

### Controls

As shown in FIGS. 1 and 1A, a control panel 110 may be located on housing 102. Control panel 110 optionally includes buttons, switches, dials, and indicator lights and the like. Control panel 100 may optionally include buttons for an air ionizer 126, fans 122, and/or a night light 120, for example. In some embodiments, buttons can be used to control a UV LED assembly. Control panel 110 may further optionally include indicator lights and which alert the user to clean pre-filter 130, electrostatic precipitator cell 150, photo-catalytic oxidizing assembly 136, or to change a UV LED assembly. Control panel 110 can include indicator lights 124 to display a fan speed. Control panel 110 can be advantageously disposed on outer top of housing 102, thus allowing a user to easily view indicators. Air cleaner 100 can be provided with a remote sensor 106 (shown in FIG. 1) and a remote control (not shown) to control remotely air cleaner 100. Air cleaner 100 can be configured to receive power from an external power source or battery. The external power source can generate a direct current (DC) high voltage for an electrostatic precipitator cell. The voltage is typically on the order of thousands of volts or even tens of thousands of volts.

In one embodiment, air cleaner 200 (as shown in FIG. 2) can comprise a control circuit (not shown) that can control the overall operation of air cleaner 200. The control circuit can be connected to control panel overlay 280 as shown in FIG. 2. In some embodiments, the control circuit can accept user input from a remote control via a remote sensor. The control circuit can receive user inputs through control panel overlay 280. The control circuit can generate outputs to the control panel overlay 280, such as lighting indicator lights, for example. In addition, in some embodiments the control circuit is connected to fans 234, the high voltage power supply (not shown), UV light bulb assembly (not shown), front panel 258 or rear panel 260 and/or a shut-down circuit (not shown). The control circuit, in some embodiments, can sense a state of one or more of these components. The control circuit, in some embodiments, can send signals, commands, or the like to one or more of these components. The control circuit, in some embodiments, can receive signals, feedback, or other data from these components. The control circuit, in some embodiments, is coupled to and communicated with the shut-down circuit. The control circuit can shut down power to fans 234, electrostatic precipitator cell 224, and/or the high voltage power supply module 276 when front panel 258 or rear panel 260 is opened. In one embodiment, only when electrostatic precipitator cell safety switch actuator 154 activates a safety switch (not shown) in housing 102 when the electrostatic precipitator cell 150 is properly inserted into electrostatic precipitator cell receptacle 146 can electricity be provided to the electrostatic precipitator cell 150. In an alternate embodiment, only when door safety switch actuators (not shown) on front panel 258 (see FIG. 2) activate a door safety switch (152) on housing 102 when the front panel 258 is properly inserted into the housing can electricity be supplied to control panel 110. In some embodiments, the control circuit can shut down power to fans 234, electrostatic precipitator cell 224, and/or the high-voltage power supply module 276 when one of the filtering components needs cleaning or servicing.

The shut-down circuit can be configured to monitor an electrical current supplied to electrostatic precipitator cell 224, to remove electrical power to electrostatic precipitator cell 224 if the electrical current exceeds a predetermined cell current threshold for a predetermined time period, and to generate an indication, such as due to arcing. The shut-down circuit can be located between the high voltage power supply and electrostatic precipitator cell 224, wherein the shut-down circuit can interrupt the electrical power that is supplied to electrostatic precipitator cell 224. As a result, the shut-down circuit can make or break the power lines between the high voltage power supply and electrostatic precipitator cell 224. It should be noted that electrical power to fans 234 can be maintained or can be terminated when the electrical power to electrostatic precipitator cell 224 is removed. The control circuit can illuminate a clean electrostatic precipitator assembly indicator based on a run time of electrostatic precipitator cell 224. In some embodiments, air cleaner 200 can be operated without electrostatic precipitator cell 224 disposed therein. When air cleaner 200 operates without electrostatic precipitator cell 224, the control circuit can be programmed to not increment the run-time of electrostatic precipitator cell 224.

After an arc or short has exceeded the predetermined time period, an indication can be generated. The indication in one embodiment comprises a light that is illuminated. The indication can include a steady illumination or a blinking illumination. Alternatively, other trouble indications can be generated including audible signals. The indication can be generated until a power cycle of air cleaner 200 occurs.

The shut-down circuit can be configured to monitor the open or closed status of front panel 258 or rear panel 260 and to remove electrical power to a UV LED assembly if front panel 258 or rear panel 260 is removed when the power is on. Alternately, the shut-down circuit can be configured to monitor the open or closed status of front panel 258 or rear panel 260 and remove electrical power to fans 234 if front panel 258 or rear panel 260 is removed when the power is on. It should be noted that electrical power to fans 234 can be maintained or terminated when the electrical power to a UV LED assembly is removed. Alternatively, it should also be noted that electrical power to a UV LED assembly can be maintained or terminated when the electrical power to fans 234 is removed. The shut-down circuit can be configured to monitor the open or closed status of front panel 258 or rear panel 260 and to remove electrical power to a UV LED assembly and fans 234 if front panel 258 or rear panel 260 is removed when the power is on.

Power can be restored to the circuit when a power cycle occurs. The power cycle can comprise a person pressing the power button. In addition or alternatively, the power cycle can comprise a person unplugging air cleaner 200 from a power outlet. Other power cycle actions are contemplated and are within the scope of the description and claims.

Once a power cycle has occurred, electrical power is restored to the component that had been interrupted. Thus, power is restored to electrostatic precipitator cell 224, fans 234, a UV light bulb assembly, etc., and the specific component, therefore, resumes operation. In addition, the indication is terminated.

A “dry mode” operating circuit can be configured to dry the electrostatic precipitator cell 224 after cleaning. While in “dry mode” fans 234 run on medium speed, and no power is supplied to the electrostatic precipitator cell 224. Once “dry mode” is selected for a use, fans 234 can run for a pre-determined time period. For example, fans may run for 15, 30, 45, 60, or more minutes. Additionally, the dry mode operating circuit may sense moisture within electrostatic precipitator cell 224. Multiple cycles of fan runs may be programmed depending upon moisture levels. Once the fans 234 have run for the pre-set run time, or when the circuit senses a sufficient level of dryness, power to the electrostatic precipitator cell 224 may be reestablished. Further, selection of “dry mode” may be indicated by an indicator light dedicated to “dry mode” on control panel overlay 280. Alternatively, selection of “dry mode” may produce a blinking pattern on an existing light on the control panel.

### Accessories

Additionally, an air cleaner may contain additional accessories which aid in the function or maintenance of the air cleaner. Non-limiting examples of such accessories include remote controls, cleaning brushes, handles, screw drivers, cords, etc. The air cleaner housing may optionally be configured to further house optional accessories in discrete interior or exterior drawers, compartments or chambers, allowing for immediate access and use of any accessory. The optional accessories may be held in the drawers, compartments or chambers via tie-downs, clamps, cut-outs, etc.

The air cleaner can be implemented according to any of the embodiments in order to obtain several advantages, if desired. The invention can provide an effective and efficient air cleaner with increased cleaning surface area, increased efficiency and increased longevity. Advantageously, the independent components enable the installation and removal of components for maintenance and repair. For example, the corona wire assembly can easily be removed and replaced as an entire unit in order to maintain or repair the air cleaner. In addition, the airflow will be optimally cleaned before reaching the fan assembly, extending motor life and lowering operating costs. Finally, the air cleaner is capable of cleaning the air efficiently and thoroughly by limiting current to the ionizer in relation to the fan speed, thereby reducing improving air cleaner efficiency, and extending the life of the corona wires, ultimately reducing operation and energy costs. As a result, air cleaners according to the present teachings are quieter, consume less power to function, and have minimal arcing—all while producing cleaner air. The various embodiments described above are provided by way of illustration only and should not be construed to limit the invention. Those skilled in the art will readily recognize the various modifications and changes which may be made to the present invention without strictly following the exemplary embodiments illustrated and described herein, and without departing from the true spirit and scope of the present invention, which are set forth in the following claims.

What is claimed is:

1. A corona wire assembly comprising:
a first supporting member including a retaining device;
a second supporting member including a retaining device;
a corona wire capable of carrying a high voltage disposed between the first supporting member and the second supporting member; and
a ground discharge electrode disposed between the first supporting member and the second supporting member;
wherein the corona assembly is separately installed and removed from an electrostatic precipitator.

2. The corona wire assembly of claim 1, wherein the corona wire comprises a plurality of corona wires, and the ground discharge electrode comprises a plurality of ground discharge electrodes interspersed between the corona wires.

3. The corona wire assembly of claim 1, further comprising an electrical contact for connecting to an off-assembly power supply disposed on an outer planar surface of the first supporting member.

4. The corona wire assembly of claim 1, wherein the retaining devices comprise projections, tabs, or planar surfaces, and are releasably retained in an electrostatic precipitator by a corresponding groove, slot, hole, or by friction fit.

5. The corona wire assembly of claim 1, wherein each of the first and second members comprises a retaining slot for retaining the corona wire.

6. An air cleaner comprising:
an air duct including an inlet and an outlet;
an electrostatic precipitator cell comprising a corona wire assembly and a collection assembly positioned in the air duct;
the collection plate assembly positioned downstream of the corona wire assembly;
wherein the corona assembly is installed and removed from the electrostatic precipitator cell and comprises:
a first supporting member including a retaining device,
a second supporting member including a retaining device,
a corona wire capable of carrying a high voltage disposed between the first supporting member and the second supporting member, and
a ground discharge electrode disposed between the first supporting member and the second supporting member.

7. The air cleaner of claim 6, further comprising:
a tab on an outer surface of the corona wire assembly; and
a tab receiver on the collection assembly,
wherein the electrostatic precipitator cell is assembled by disposing the tab of the corona wire assembly into the tab receiver of the collection assembly.

8. The air cleaner of claim 6, further comprising:
a high voltage power supply;
an electrical contact on the corona wire assembly; and
an electrostatic precipitator cell receiver including an electrical contact on,
wherein contact between the electrical contact of the corona wire assembly and the electrical contact on the electrostatic precipitator cell receiver connects the corona wire assembly to the high voltage power supply.

9. The air cleaner of claim 8, further comprising a fan operable at different speeds.

10. The air cleaner of claim 9, wherein an amplitude of an electrical current supplied to the corona wire assembly by the high power voltage supply correlates to the speed of the fan.

11. The air cleaner of claim 6, further comprising:
a high voltage power supply;
an electrical contact on the collection assembly; and
an electrostatic precipitator cell receiver including an electrical contact,
wherein contact between the electrical contact of the collection assembly and the electrical contact on the electrostatic precipitator cell receiver connects the collection assembly to the high voltage power supply.

12. An electrostatic precipitator cell comprising:
a corona wire assembly comprising:
a first supporting member including a retaining device,
a second supporting member including a retaining device,
a corona wire capable of carrying a high voltage disposed between the first supporting member and the second supporting member, and
a ground discharge electrode disposed between the first supporting member and the second supporting member; and
a collection assembly positioned downstream of the corona wire assembly,
wherein the corona assembly is detachably installed and removed from the electrostatic collection assembly.

13. The electrostatic precipitator cell of claim 12, further comprising:
a tab on an outer surface of the corona wire assembly; and
a tab receiver on the collection assembly,
wherein the electrostatic precipitator cell is assembled by disposing the tab of the corona wire assembly into the tab receiver of the collection assembly.

14. The electrostatic precipitator cell of claim 12, further comprising:
an electrical contact on the corona wire assembly; and
an electrical contact on an electrostatic precipitator cell receiver,
wherein contact between the electrical contact of the corona wire assembly and the electrical contact on the electrostatic precipitator cell receiver connects the corona wire assembly to a high voltage power supply.

15. The electrostatic precipitator cell of claim 12, further comprising:
an electrical contact on the collection assembly; and
an electrical contact on the electrostatic precipitator cell receiver,
wherein contact between the electrical contact of the collection assembly and the electrical contact on the electrostatic precipitator cell receiver connects the collection assembly to a high voltage power supply.

16. A process of replacing a corona wire assembly, the process comprising:
providing a corona wire assembly, wherein the corona wire assembly comprises,
a first supporting member including a retaining device;
a second supporting member including a retaining device;
a corona wire capable of carrying a high voltage disposed between the first supporting member and the second supporting member;
a ground discharge electrode disposed between the first supporting member and the second supporting member; and
separately installing or removing the corona wire assembly from an electrostatic precipitator.
